(19) United States
(12) Patent Application Publication
(10) Pub. No.: US 2026/0059782 A1
(43) Pub. Date: Feb. 26, 2026

(54) SEMICONDUCTOR STRUCTURE AND METHOD FOR MANUFACTURING THEREOF

(71) Applicant: ENKRIS SEMICONDUCTOR, INC., Suzhou (CN)

(72) Inventor: Kai CHENG, Suzhou (CN)

(21) Appl. No.: 19/046,450

(22) Filed: Feb. 5, 2025

(30) Foreign Application Priority Data
Aug. 21, 2024 (CN) 202411155091.6

(51) Int. Cl. H10D 30/47; H10D 30/01; H10D 62/10; H10D 62/17; H10D 62/815; H10D 62/85

(52) U.S. Cl. CPC H10D 30/4732; H10D 30/015; H10D 62/125; H10D 62/221; H10D 62/8171; H10D 62/8503

(57) ABSTRACT

The embodiment of the present disclosure provides a semiconductor structure and a method for manufacturing thereof, the semiconductor structure includes a substrate and a channel structure at a side of the substrate, and the channel structure includes a first channel layer and a first barrier layer which are sequentially disposed at a side of the substrate; where the semiconductor structure includes a gate region, and a source region and a drain region at both sides of the gate region, the channel structure in the source region is provided with a first groove, and the channel structure in the drain region is provided with a second groove; and two N-type heavily doped layers are in the first groove and the second groove respectively, where a surface of the N-type heavily doped layers away from the substrate has a plurality of V-shaped pits.

### CROSS REFERENCE TO RELATED APPLICATIONS

This application claims priority to Chinese Patent Application No. 2024111550916 entitled “SEMICONDUCTOR STRUCTURE AND METHOD FOR MANUFACTURING THEREOF” filed on Aug. 21, 2024, the entire content of which is incorporated herein by reference.

### TECHNICAL FIELD

The present disclosure relates to the technical field of semiconductors, in particular to a semiconductor structure and a method for manufacturing thereof.

### BACKGROUND

During a manufacturing process of a GaN-based high electron mobility transistor (HEMT) device, a source-drain ohmic contact process is one of the key technologies, which directly affects the frequency and the power performance of the device. Therefore, it is of great significance to effectively reduce the overall ohmic contact resistance of the GaN-based HEMT device.

### SUMMARY

In view of this, the present disclosure provides a semiconductor structure and a method for manufacturing thereof.

In a first aspect, the present disclosure provides a semiconductor structure, including: a substrate; a channel structure at a side of the substrate, where the channel structure includes a first channel layer above the substrate and a first barrier layer above the first channel layer; where the semiconductor structure includes a gate region, and a source region and a drain region at both sides of the gate region, the channel structure in the source region is provided with a first groove, and the channel structure in the drain region is provided with a second groove; and two N-type heavily doped layers respectively located in the first groove and the second groove; where a surface of the N-type heavily doped layer away from the substrate has a plurality of V-shaped pits.

In a second aspect, the present disclosure provides a method for manufacturing a semiconductor structure, including: providing a substrate; forming a channel structure above the substrate, where the semiconductor structure includes a gate region, and a source region and a drain region at both sides of the gate region, and the channel structure includes a first channel layer above the substrate and a first barrier layer above the first channel; and forming N-type heavily doped layers in the first groove and the second groove, respectively, where a plurality of V-shaped pits are formed at a surface of the N-type heavily doped layer away from the substrate.

### BRIEF DESCRIPTION OF DRAWINGS

FIG. 1 is a schematic diagram of a cross section of a semiconductor structure according to an embodiment of the present disclosure.

FIG. 2 is a schematic diagram of a cross section of a semiconductor structure according to an embodiment of the present disclosure.

FIG. 3 is a schematic diagram of a cross section of a semiconductor structure according to an embodiment of the present disclosure.

FIG. 4 is a schematic diagram of a cross section of a semiconductor structure according to an embodiment of the present disclosure.

FIG. 5 is a schematic diagram of a cross section of a semiconductor structure according to an embodiment of the present disclosure.

FIG. 6 is a schematic diagram of a cross section of a semiconductor structure according to an embodiment of the present disclosure.

FIG. 7 is a schematic diagram of a cross section of a semiconductor structure according to an embodiment of the present disclosure.

FIG. 8 is a schematic diagram of a cross section of a semiconductor structure according to an embodiment of the present disclosure.

FIG. 9 is a schematic diagram of a cross section of a semiconductor structure according to an embodiment of the present disclosure.

FIG. 10 is a schematic diagram of a cross section of a semiconductor structure according to an embodiment of the present disclosure.

FIG. 11 is a flowchart of a method for manufacturing a semiconductor structure according to an embodiment of the present disclosure.

FIGS. 12 to 15 are schematic diagrams of cross sections for intermediate structures of a method for manufacturing a semiconductor structure according to an embodiment of the present disclosure.

FIG. 16 is a flowchart of a method for manufacturing a semiconductor structure according to an embodiment of the present disclosure.

FIG. 17 is a schematic diagram of a cross section for an intermediate structure of a method for manufacturing a semiconductor structure according to an embodiment of the present disclosure.

FIG. 18 is a flowchart of a method for manufacturing a semiconductor structure according to an embodiment of the present disclosure.

FIGS. 19 to 22 are schematic diagrams of cross sections for intermediate structures of another method for manufacturing a semiconductor structure according to an embodiment of the present disclosure.

### REFERENCE NUMBER DESCRIPTION

10—substrate; 101—buffer layer; 20—channel structure; 11—gate region; 12—source region; 13—drain region; 21—first channel layer; 22—first barrier layer; 30 —first groove; 40—second groove; 50—N-type heavily doped layer; 51—V shaped pit; 52—cap layer; 53—back barrier layer; 54—second channel layer; 55—second barrier layer; 70—drain electrode; 80—gate electrode.

### DETAILED DESCRIPTION

In order to make those skilled in the art better understand the solutions of the present disclosure, the technical solutions in the embodiments of the present disclosure will be clearly and completely described below with reference to the accompanying drawings in the embodiments of the present disclosure. Obviously, the described embodiments are only a portion of embodiments of the present the present disclosure and not all embodiments of the present the present disclosure. It should be understood that the terms first, second, etc. used in the present disclosure are merely used to distinguish information of the same type from each other, and are not necessarily used to describe a specific order or sequence.

GaN-based HEMT devices exhibit excellent performance in terms of the high breakdown voltage, the low conduction resistance, and the immunity of the hot carrier. However, the ohmic contact resistance in the high electron mobility transistors is relatively large, which needs to be improved.

During the manufacturing process of the GaN-based HEMT devices, manufacturing the N-type heavily doped layers in the ohmic contact region to reduce the ohmic contact resistivity has become a new process in recent years, at the international level. The ohmic contact resistance realized by this process mainly includes a contact resistance between the metal and the N-type heavily doped layer, and a contact resistance between the N-type heavily doped layer and the side wall of the heterojunction in the channel structure. The contact status between the N-type heavily doped layer and the sidewall of the heterojunction in the channel structure directly affects the contact resistance between the N-type heavily doped layer and the heterojunction in the channel structure, and this contact resistance has the greatest influence on the overall ohmic contact resistance.

To alleviate the problem that the contact resistance of the semiconductor device is too high, the present disclosure provides a semiconductor structure, by reducing the ohmic contact resistance, to improve the performance such as the microwave and the high frequency (terahertz) of the HEMT device. In the following, a semiconductor structure used for a HEMT device is described as an example.

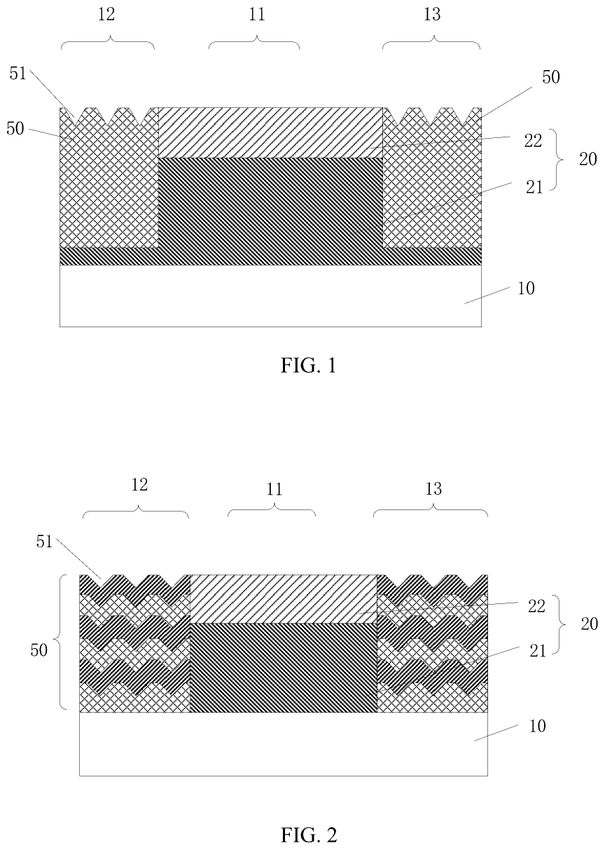

FIG. 1 is a schematic diagram of a cross section of a semiconductor structure according to an embodiment of the present disclosure. As shown in FIG. 1, the present disclosure provides a semiconductor structure including a substrate 10, a channel structure 20 at a side of the substrate 10, and two N-type heavily doped layers 50.

In some embodiments, the channel structure 20 includes a first channel layer 21 and a first barrier layer 22 which are sequentially disposed at the side of the substrate 10. The semiconductor structure includes a gate region 11, and a source region 12 and a drain region 13 respectively at both sides of the gate region 11. The channel structure 20 in the source region 12 is provided with a first groove 30, and the channel structure 20 in the drain region 13 is provided with a second groove 40.

In some embodiments, the two N-type heavily doped layers 50 are respectively in the first groove 30 and the second groove 40. The N-type heavily doped layer 50 may be made of N-type doped group III nitride materials, and the N-type heavily doped layer 50 may be a single-layer structure or a superlattice structure. The N-type element doped in the N-type heavily doped layer 50 may include at least one of Si, Ge, Sn, Se, or Te. The doping concentration of the N-type element may be greater than 1E18/cm³. The higher the doping concentration of the N-type element, the smaller the contact resistance between the N-type heavily doped layer 50 and the source electrode or between the N-type heavily doped layer 50 and the drain electrode.

The surface of the N-type heavily doped layer 50 away from the substrate 10 has a plurality of V-shaped pits 51, which can increase the contact area between the source electrode and the N-type heavily doped layer 50 or between the drain electrode and the N-type heavily doped layer 50, thereby reducing the contact resistance between the source electrode and the N-type heavily doped layer 50 or between the drain electrode and the N-type heavily doped layer 50.

Optionally, the V-shaped pits 51, due to the differences in crystal plane growth orientations and growth rates at the different positions resulting from the dislocation defects in the N-type heavily doped layer 50, are spontaneously formed. Specifically, the V-shaped pits 51 may be formed in a low temperature epitaxy process. Compared with the surface roughening treatment, the V-shaped pits 51 grown in low-temperature are uniformly distributed, the inner side crystal planes of the V-shaped pits are stable, which can result in the stable current transmission, thereby alleviating the problem of leakage of the HEMT device and reducing the energy consumption of the HEMT device. In some embodiments, the N-type heavily doped layer 50 may be formed in a low-temperature growth mode. For example, the N-type heavily doped layer 50 is epitaxially grown at 800° C. to 900° C. The density of the V-shaped pits 51 may be increased by adjusting the process parameters, such as the temperature, the pressure, the gas flow rate, etc., of the low temperature growth, which may further increase the contact area between the source electrode and the N-type heavily doped layer 50 or between the drain electrode and the N-type heavily doped layer 50, thereby reducing the contact resistance between the source electrode and the N-type heavily doped layer 50 or between the drain electrode and the N-type heavily doped layer 50.

In some embodiments, when the N-type heavily doped layer 50 is a single-layer structure, the N-type heavily doped layer 50 may be an N-type heavily doped InGaN layer.

FIG. 2 is a schematic diagram of a cross section of a semiconductor structure according to an embodiment of the present disclosure. As shown in FIG. 2, in some embodiments, when the N-type heavily doped layer 50 is a superlattice structure, the N-type heavily doped layer 50 includes at least two periodically stacked material layers, and the at least two material layers are respectively selected from an InGaN layer, a GaN layer, a GaAs layer, an AlGaAs layer, or an InGaAs layer. For example, the N-type heavily doped layer 50 is formed by InGaN layers and GaN layers which are stacked alternately; the surface of each InGaN layer away from the substrate 10 and the surface of each GaN layer away from the substrate 10 both have a plurality of V-shaped pits. For another example, the N-type heavily doped layer 50 is formed by InGaN layers, GaN layers and GaAs layers which are stacked alternately. The surface of each InGaN layer away from the substrate 10, the surface of each GaN layer away from the substrate 10, and the surface of each GaAs layer away from the substrate 10 both have a plurality of V-shaped pits. In some embodiments, a cross-sectional width of the V-shaped pit 51 in the direction perpendicular to the substrate 10 gradually increases along a direction away from the substrate. That is, the vertical section of the V-shaped pit 51 is approximately V-shaped, the tip of the V-shaped pit 51 is close to the substrate 10, and the opening end of the V-shaped pit 51 is away from the substrate 10. It should be noted that the shape of the V-shaped pit 51 is a hexagonal cone.

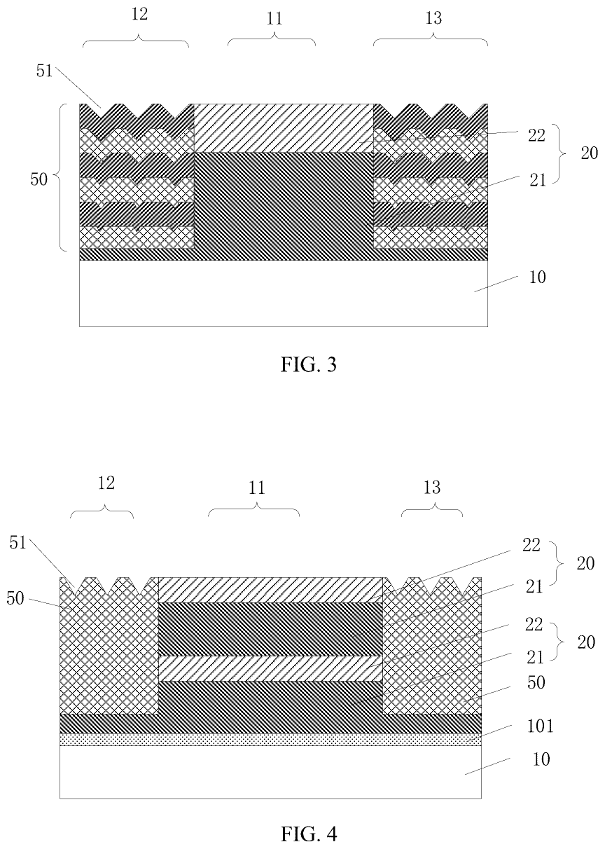

FIG. 3 is a schematic diagram of a cross section of a semiconductor structure according to an embodiment of the present disclosure. As shown in FIG. 3, in some embodiments, the opening width of the V-shaped pit in the material layer away from the substrate 10 is greater than the opening width of the V-shaped pit in the material layer close to the substrate 10. When the N-type heavily doped layer 50 is a superlattice structure, each material layer sequentially secondary epitaxially grows on the previous material layer, and the secondary epitaxial growth can enlarge the V-shaped pit, that is, the opening width of the V-shaped pit in the material layer formed later is greater than the opening width of the V-shaped pit in the material layer formed earlier. In other words, the opening width of the V-shaped pit of the material layer away from the substrate 10 is greater than the opening width of the V-shaped pit of the material layer close to the substrate 10. The enlarged V-shaped pit can effectively release stress caused by the lattice mismatch and the thermal mismatch between the semiconductor structure and the heterogeneous substrate, in secondary epitaxial growth, the lateral epitaxy is realized due to the difference between the bottom and side wall of the V-shaped pit in growth orientation and growth rate, which can effectively reduce the dislocation density, improve the crystal quality of the semiconductor structure, and reduce the cracks of the semiconductor structure. In addition, the opening width of the V-shaped pit in the material layer formed last and farthest away from the substrate 10 is the largest opening width, which can further increase the contact area between the source electrode and the N-type heavily doped layer 50 or between the drain electrode and the N-type heavily doped layer 50, thereby reducing the contact resistance between the source electrode and the N-type heavily doped layer 50 or between the drain electrode and the N-type heavily doped layer 50.

FIG. 4 is a schematic diagram of a cross section of a semiconductor structure according to an embodiment of the present disclosure. As shown in FIG. 4, in some embodiments, the semiconductor structure includes a plurality of channel structures 20 disposed above the substrate 10, that is, the semiconductor structure includes a plurality of first channel layers 21 and a plurality of first barrier layers 22 disposed alternately and each channel structure includes a first channel layer 21 and a first barrier layer 22 above the first channel layer 21. Bottoms of the first groove 30 and the second groove 40 are respectively lower than the surface away from the substrate 10 of the first channel layer 21 of the channel structure 20 closest to the substrate 10.

The first groove 30 and the second groove 40 partly penetrate through the first channel layer 21 closest to the substrate 10, that is, a part of the first channel layer 21 is between the N-type heavily doped layer 50 and the substrate 10, so that the breakdown of the substrate 10 can be avoided. The bottoms of the first groove 30 and the second groove 40 are lower than the surface away from the substrate 10 of the first channel layer 21 closest to the substrate 10, so that the 2DEG (two-dimensional electron gas) concentration in the channel structure 20 can be increased, and the on-resistance of the device can be reduced.

As shown in FIG. 4, in some embodiments, a buffer layer 101 may be further disposed between the channel structure 20 and the substrate 10. The buffer layer 101 may be made of at least one of AlN, GaN, AlGaN, and AlInGaN. The buffer layer 101 may reduce the dislocation density and the defect density of the semiconductor layer epitaxially grown thereon, and improve the crystal quality.

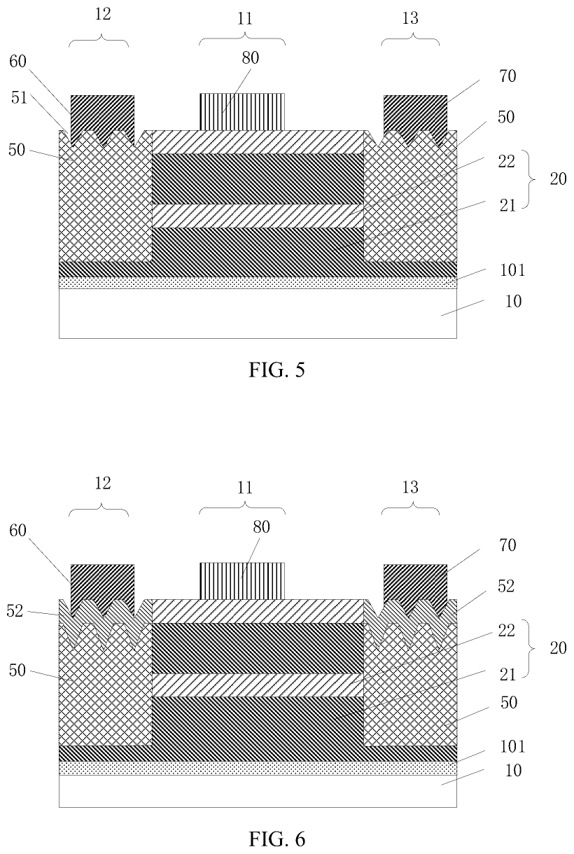

FIG. 5 is a schematic diagram of a cross section of a semiconductor structure according to an embodiment of the present disclosure. As shown in FIG. 5, in some embodiments, the semiconductor structure further includes a gate electrode 80 in the gate region 11, and a source electrode 60 and a drain 70 in the source region 12 and the drain region 13, respectively. The gate electrode 80 is at a side of the channel structure 20 away from the substrate 10. The source electrode 60 and the drain electrode 70 are respectively at a side of the two N-type heavily doped layers 50 away from the substrate 10. The source electrode 60 and the drain electrode 70 respectively fill the V-shaped pits 51, that is, the contact surfaces between the N-type heavily doped layer 50 and the source electrode 60 and between the N-type heavily doped layer 50 and the drain electrode 70 are non-planar, and compared with the N-type heavily doped layer without pits on the surface, the contact area is larger, thereby reducing the contact resistance between the source electrode and the N-type heavily doped layer 50 or between the drain electrode and the N-type heavily doped layer 50.

FIG. 6 is a schematic diagram of a cross section of a semiconductor structure according to an embodiment of the present disclosure. As shown in FIG. 6, in some embodiments, the semiconductor structure further includes two cap layers 52. The two cap layers 52 respectively cover the surfaces of the two N-type heavily doped layers 50 away from the substrate 10. That is, the difference between the semiconductor structure of this embodiment and the semiconductor structure shown in FIG. 5 is that the cap layers 52 are further disposed between the source electrode 60 and the N-type heavily doped layer 50 and between the drain 70 and the N-type heavily doped layer 50. Optionally, the cap layer 52 conformally covers the N-type heavily doped layer 50. Since the cap layer 52 conformally covers the N-type heavily doped layer 50, the surface of the cap layer 52 also has pits. That is, the opening width of the V-shaped pit of the surface of the cap layer 52 is substantially equal to the opening width of the V-shaped pit 51 at the surface of the N-type heavily doped layer 50. The cap layer 52 may be made of AlGaN. The cap layer 52 may serve as a protective layer to protect the N-type heavily doped layer 50.

Optionally, a distance between a surface of the N-type heavily doped layer 50 away from the substrate 10 and the substrate 10 is greater than or equal to a distance between a surface of the first channel layer 21 away from the substrate 10 and the substrate 10. Specifically, the N-type heavily doped layer 50 is at least in contact with the channel in the first channel layer 21, which can increase the 2DEG concentration in the channel structure 20.

Optionally, as shown in FIG. 6, in a case where the semiconductor structure includes first channel layers 21 and first barrier layers 22 which are alternately disposed, a surface (that is, the plane between the V-shaped pits in the cap layer 52) of the cap layer 52 away from the substrate 10 may be flush with a surface (away from the substrate 10) of the first barrier layer 22 farthest away from the substrate 10; or a surface of the cap layer 52 close to the substrate 10 may be flush with a surface (away from the substrate 10) of the first channel layer 21 farthest away from the substrate 10, that is, an upper surface of the N-type heavily doped layer 50 is substantially flush with an upper surface of the first channel layer 21 farthest away from the substrate 10. Specifically, new 2DEG is formed between the cap layer 52 and the N-type heavily doped layer 50, where the upper surface of the N-type heavily doped layer 50 is flush with the upper surface of one of the first channel layers 21, and the newly formed 2DEG is connected in series with the 2DEG in the channel structure, so that the contact resistance between the N-type heavily doped layer 50 and the heterojunction in the channel structure 20 can be reduced, and the overall ohmic contact resistance of the HEMT device is further reduced.

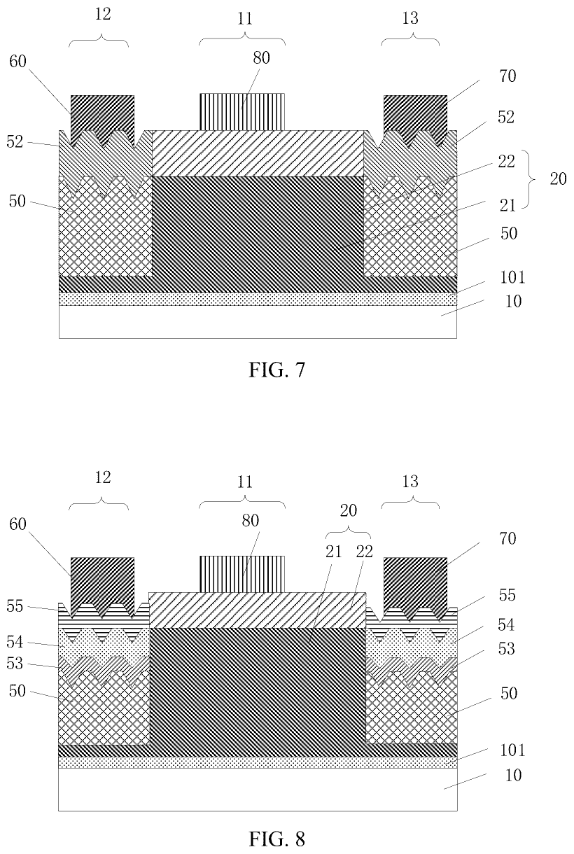

In some embodiments, as shown in FIG. 7, in a case where the semiconductor structure includes one first channel layer 21 and one first barrier layer 22, the surface (that is, a plane between the V-shaped pits in the cap layer 52) of the cap layer 52 away from the substrate 10 may be flush with the surface of the first barrier layer 22 away from the substrate 10; or a surface of the cap layer 52 close to the substrate 10 may be flush with a surface of the first channel layer 21 away from the substrate 10, that is, an upper surface of the N-type heavily doped layer 50 is flush with an upper surface of the first channel layer 21.

FIG. 8 is a schematic diagram of a cross section of a semiconductor structure according to an embodiment of the present disclosure. As shown in FIG. 8, in some embodiments, the semiconductor structure further includes: a back barrier layer 53, a second channel layer 54 and a second barrier layer 55 which are sequentially disposed on the N-type heavily doped layer 50.

In some embodiments, the back barrier layer 53 conformally covers the N-type heavily doped layer 50, and the back barrier layer 53 includes back barrier layer V-shaped pits. For example, the back barrier layer 53 is made of AlN or AlGaN. The thickness of the back barrier layer 53 is relatively thin, and the thickness of the back barrier layer 53 is less than the thickness of the N-type heavily doped layer 50 and less than the thickness of the second channel layer 54.

Optionally, as shown in FIG. 8, the second channel layer 54 conformally covers the back barrier layer 53, and the second channel layer 54 includes the second channel layer V-shaped pits. The second channel layer 54 is made of GaN based material, for example, the second channel layer 54 is made of unintentionally doped GaN (uGaN).

Optionally, the second barrier layer 55 conformally covers the second channel layer 54, and the second barrier layer 55 includes second barrier layer V-shaped pits. For example, the second barrier layer 55 is made of AlGaN.

Specifically, new 2DEG may be formed between the second channel layer 54 and the second barrier layer 55, where a surface of the second channel layer 54 away from the substrate 10 is flush with a surface of the first channel layer 21 away from the substrate 10, that is, an upper surface of the second channel layer 54 is flush with an upper surface of the first channel layer 21, and which results in that the newly formed 2DEG and the 2DEG in the channel structure are connected to each other, thereby reducing a contact resistance between a heterojunction formed by the second channel layer 54 and the second barrier layer 55 and a heterojunction in the channel structure, further reducing the resistance between the source electrode and the N-type heavily doped layer 50 and the resistance between the drain electrode and the N-type heavily doped layer 50, and reducing the overall ohmic contact resistance of the HEMT device.

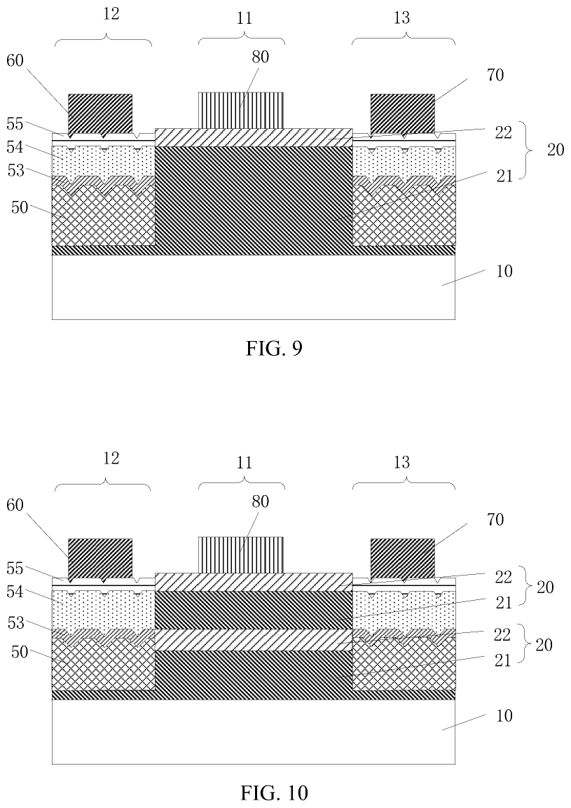

Optionally, as shown in FIG. 9, the opening width of the back barrier layer V-shaped pit is greater than the opening width of the second channel layer V-shaped pit, and the opening width of the second channel layer V-shaped pit is greater than the opening width of the second barrier layer V-shaped pit. In other words, along the direction from the substrate 10 to the back barrier layer 53, the opening width of the V-shaped pit of the semiconductor layers in the source region 12 and the drain region 13 gradually decreases. Optionally, the depth of the back barrier layer V-shaped pit is greater than the depth of the second channel layer V-shaped pit, and the depth of the second channel layer V-shaped pit is greater than the depth of the second barrier layer V-shaped pit; in other words, along the direction from the substrate 10 to the back barrier layer 53, the depth of the V-shaped pit of the semiconductor layers in the source region 12 and the drain region 13 gradually decreases. In this way, in the epitaxy process, the surface of the semiconductor layers away from the substrate gradually tends to be planar, which can reduce defects of the layers and the stress between the layers, and is beneficial to the subsequent manufacturing of the semiconductor layers.

In addition, the back barrier layer 53 can prevent the N-type doped element in the N-type heavily doped layer 50 from diffusing to the second channel layer 54.

In some embodiments, the surface of the N-type heavily doped layer 50 away from the substrate 10 is closer to the substrate 10 than the surface of the first channel layer 21 away from the substrate 10.

In some embodiments, as shown in FIG. 10, the semiconductor structure includes a plurality of channel structures. That is, in a case that the semiconductor structure includes a plurality of first channel layers 21 and the first barrier layers 22 which are alternately disposed, a surface of the second channel layer 54 away from the substrate 10 is flush with a surface (away from the substrate 10) of the first channel layer 21 farthest away from the substrate 10. Optionally, a surface (away from the substrate 10) of another first channel layer 21 other than the first channel layer farthest away from the substrate 10 is flush with the surface of the N-type heavily doped layer 50 away from the substrate 10. In this way, on the basis that the 2DEG between the second channel layer 54 and the second barrier layer 55 is connected to the 2DEG in the channel structure, the 2DEG between the N-type heavily doped layer 50 and the back barrier layer 53 is further connected to the 2DEG in the channel structure, thereby further reducing the resistance between the source electrode 60 and the N-type heavily doped layer 50, and the resistance between the drain electrode 70 and the N-type heavily doped layer 50, and reducing the overall ohmic contact resistance of the HEMT device.

Optionally, as shown in FIG. 10, a surface (away from the substrate 10) of another first channel layer 21 other than the first channel layer 21 farthest away from the substrate 10 may be lower than the surface of the N-type heavily doped layer 50 away from the substrate 10. Optionally, a surface (away from the substrate 10) of another first channel layer 21 other than the first channel layer 21 farthest away from the substrate 10 may be higher than a surface of the N-type heavily doped layer 50 away from the substrate 10.

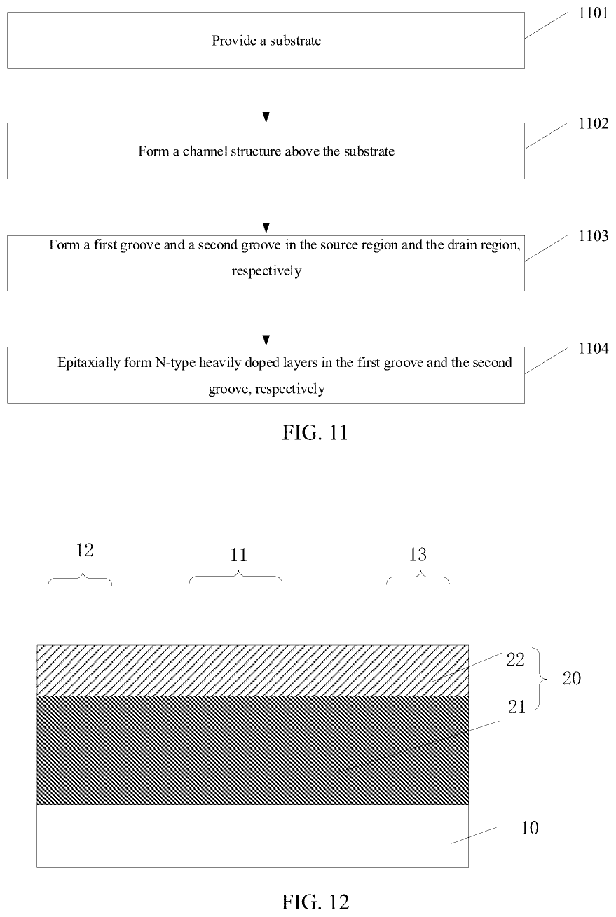

FIG. 11 is a flowchart of a method for manufacturing a semiconductor structure according to an embodiment of the present disclosure. FIGS. 12 to 15 are schematic diagrams of cross sections for intermediate structures of a method for manufacturing a semiconductor structure according to an embodiment of the present disclosure. As shown in FIGS. 11 to 15, according to the present disclosure, a method for manufacturing a semiconductor structure is provided, and the method includes the following steps.

Step 1101: a substrate 10 is provided.

As shown in FIG. 12, in some embodiments of the present disclosure, the substrate 10 may be made of a semiconductor or an oxide, the semiconductor may include silicon (Si), gallium nitride (GaN), silicon carbide (SiC), or gallium arsenide (GaAs), and the oxide may include sapphire.

Step 1102: a channel structure 20 above the substrate 10 is formed, where the semiconductor structure includes a gate region 11, and a source region 12 and a drain region 13 at two sides of the gate region 11.

As shown in FIG. 12, in some embodiments, the channel structure 20 includes a first channel layer 21 and a first barrier layer 22 sequentially disposed at a side of the substrate 10. The first channel layer 21 and the first barrier layer 22 may be made of III-V group semiconductor materials, for example, the first channel layer 21 is made of GaN, the first barrier layer 22 is made of AlGaN, and 2DEG is formed between the first channel layer 21 and the first barrier layer 22 by using a polarization effect between different GaN-based compounds.

The first channel layer 21 and the first barrier layer 22 may be formed by atomic layer deposition (ALD), chemical vapor deposition (CVD), molecular beam epitaxy (MBE), plasma enhanced chemical vapor deposition (PECVD), low pressure chemical vapor deposition (LPCVD), physical vapor deposition (PVD), metal-organic molecular beam epitaxy (MOMBE), metal-organic chemical vapor deposition (MOCVD), or a combination thereof.

Step 1103: a first groove 30 and a second groove 40 are formed in the source region 12 and the drain region 13, respectively.

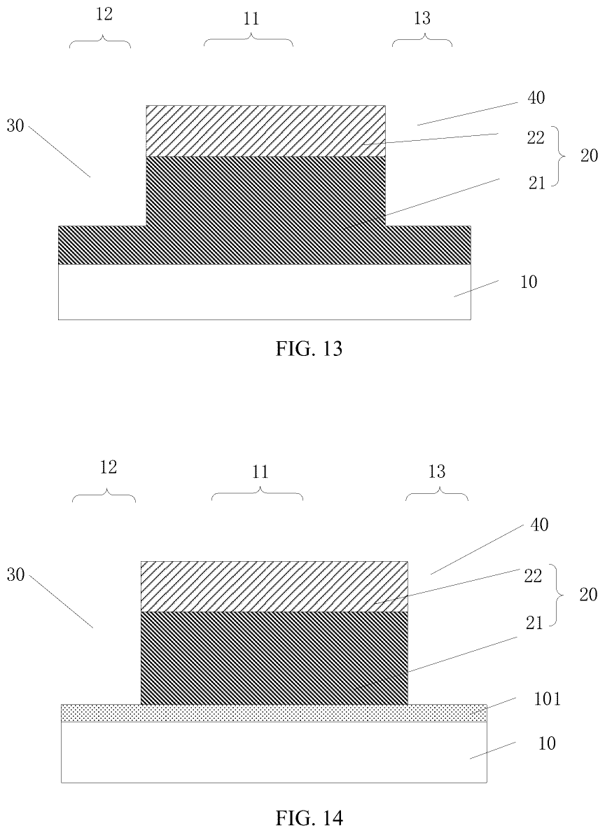

As shown in FIG. 13, in some embodiments, the first groove 30 and the second groove 40 may be formed by dry etching or wet etching. The first groove 30 and the second groove 40 penetrate through the first barrier layer 22 and partially penetrate through the first channel layer 21.

As shown in FIG. 14, in some embodiments, the first groove 30 and the second groove 40 penetrate through the first barrier layer 22 and the first channel layer 21, and a buffer layer 101 is formed between the substrate 10 and the channel structure 20. Specifically, the buffer layer has a high resistance, which can avoid the problem of breakdown caused by the N-type heavily doped layer 50 being close to the substrate 10.

Step 1104: N-type heavily doped layers 50 are epitaxially formed in the first groove 30 and the second groove 40, respectively, where a plurality of V-shaped pits 51 are formed at a surface of the N-type heavily doped layer 50 away from the substrate 10.

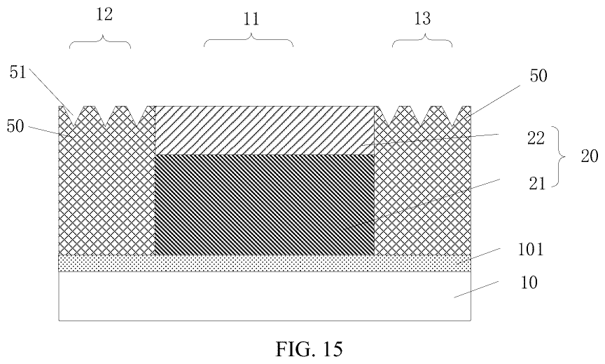

As shown in FIG. 15, in some embodiments, the N-type heavily doped layer 50 may be formed in the first groove 30 and the second groove 40 respectively through a low-temperature epitaxy process, the temperature of the low-temperature epitaxy process ranges from 800° C. to 900° C., and a plurality of V-shaped pits 51 are spontaneously formed at the surface of the N-type heavily doped layer 50 away from the substrate 10.

The N-type heavily doped layer 50 includes an N-type heavily doped GaN-based material layer, for example, an InGaN layer. The N-type element doped in the N-type heavily doped layer 50 may include at least one of Si, Ge, Sn, Se, or Te. The doping concentration of the N-type element may be greater than 1E18/cm³.

It should be noted that, before forming the N-type heavily doped layer 50, an insulating layer (not shown in FIG. 15), such as SiO₂, is disposed on the first barrier layer 22, so that the N-type heavily doped layer 50 is epitaxially grown in the first groove 30 and the second groove 40 selectively. In subsequent processes, the insulating layer may be selectively removed. In subsequent embodiments, when performing the selectively epitaxial growth process in the first groove and the second groove, the insulating layer need to be provided, which will not be repeated hereinafter.

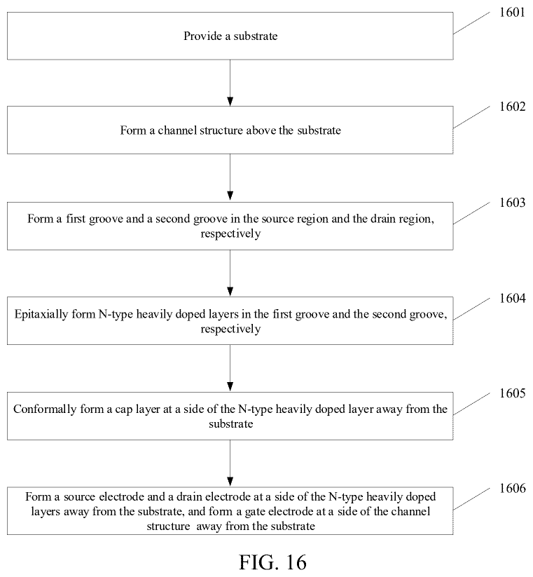

FIG. 16 is a flowchart of a method for manufacturing a semiconductor structure according to an embodiment of the present disclosure. As shown in FIG. 16, the method for manufacturing the semiconductor structure includes the following steps.

Steps 1601 to 1603 may refer to steps 1101 to 1103, and details are not described herein again.

Step 1604: N-type heavily doped layers 50 are epitaxially formed in the first groove 30 and the second groove 40 respectively, where a plurality of V-shaped pits 51 are formed at a surface of the N-type heavily doped layer 50 away from the substrate 10.

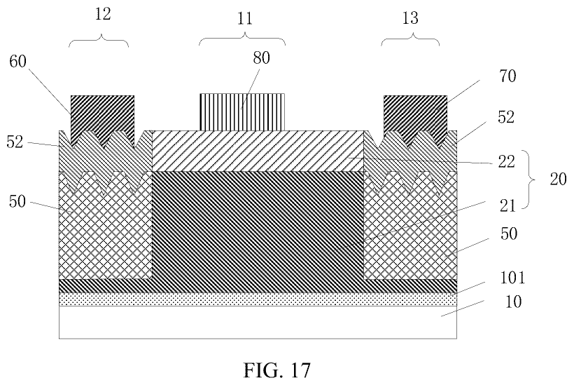

As shown in FIG. 17, the difference between step 1604 and step 1104 is that the surface of the N-type heavily doped layer 50 away from the substrate 10 is lower than the surface of the first barrier layer 22 away from the substrate 10.

Step 1605: a cap layer 52 is conformally formed at a side of the N-type heavily doped layer 50 away from the substrate 10.

As shown in FIG. 17, in some embodiments, the cap layer 52 is formed by a process such as chemical vapor deposition or epitaxial growth. According to the embodiment of the present disclosure, the N-type heavily doped layer 50 with the V-shaped pits 51 at the surface thereof is formed firstly, and then the cap layer 52 is conformally formed on the N-type heavily doped layer 50, so that the cap layer 52 with a plurality of pits on the surface thereof can be obtained, and the contact area between the cap layer 52 and the source electrode formed on the cap layer 52, or between the cap layer 52 and the drain electrode formed on the cap layer 52 can be increased, thereby reducing the ohmic contact resistance.

Step 1606: a source electrode 60 and a drain electrode 70 are formed at a side of the N-type heavily doped layers 50 away from the substrate 10, and a gate electrode 80 is formed at a side of the channel structure 20 away from the substrate 10.

As shown in FIG. 17, in some embodiments, the gate electrode 80, the source electrode 60, and the drain electrode 70 may be made of metallic materials. The gate electrode 80 is in the gate region 11 and is in contact with a surface of the first barrier layer 22 away from the substrate 10. The source electrode 60 and the drain electrode 70 are respectively in the source region 12 and the drain region 13, and the source electrode 60 and the drain electrode 70 are respectively in contact with the cap layer 52.

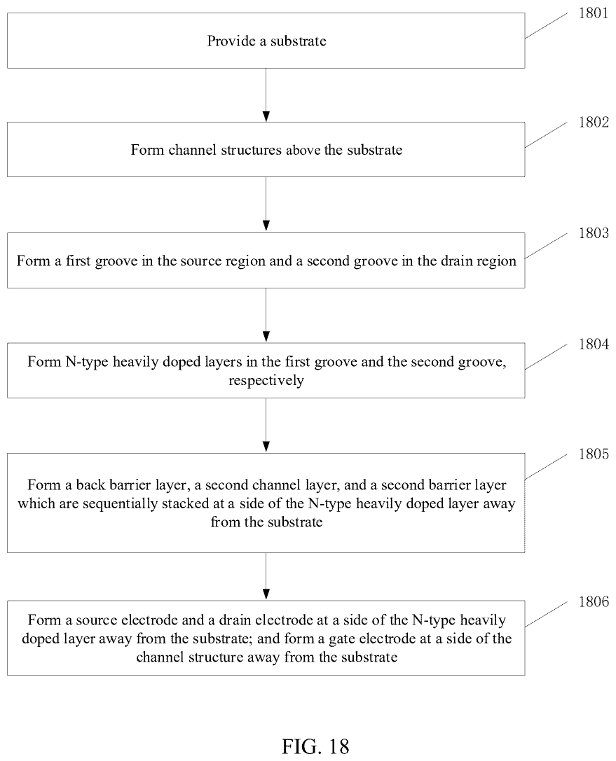

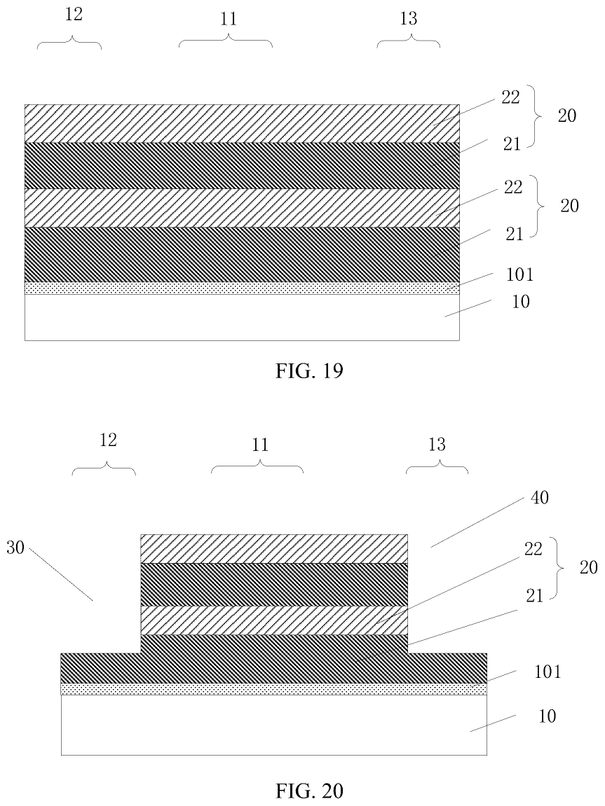

FIG. 18 is a flowchart of a method for manufacturing a semiconductor structure according to an embodiment of the present disclosure, and FIGS. 19 to 22 are schematic cross-sectional views of intermediate structures of another method for manufacturing a semiconductor structure according to an embodiment of the present disclosure. As shown in FIG. 18, the method for manufacturing the semiconductor structure includes the following steps.

Step 1801: a substrate 10 is provided.

Step 1801 may refer to step 1101, and details are not described herein again.

Step 1802: channel structures 20 are formed above the substrate 10, where the semiconductor structure includes a gate region 11, and a source region 12 and a drain region 13 at two sides of the gate region 11.

As shown in FIG. 19, in some embodiments, the channel structures 20 are stacked above the substrate 10. That is, the difference between step 1802 and step 1102 includes that a plurality of first channel layers 21 and a plurality of first barrier layers 22 are alternately formed sequentially.

Step 1803: a first groove 30 and a second groove 40 are formed in the source region 12 and the drain region 13, respectively.

As shown in FIG. 20, in some embodiments, the channel structures 20 in the source region 12 and the drain region 13 may be etched by an etching process to form a first groove 30 and a second groove 40. The bottoms of the first groove 30 and the second groove 40 are respectively lower than the surface (away from the substrate 10) of the first channel layer 21 in the channel structure 20 closest to the substrate 10.

Step 1804: N-type heavily doped layers 50 are epitaxially formed in the first groove 30 and the second groove 40 respectively, where a plurality of V-shaped pits 51 are formed at a surface of the N-type heavily doped layer 50 away from the substrate 10.

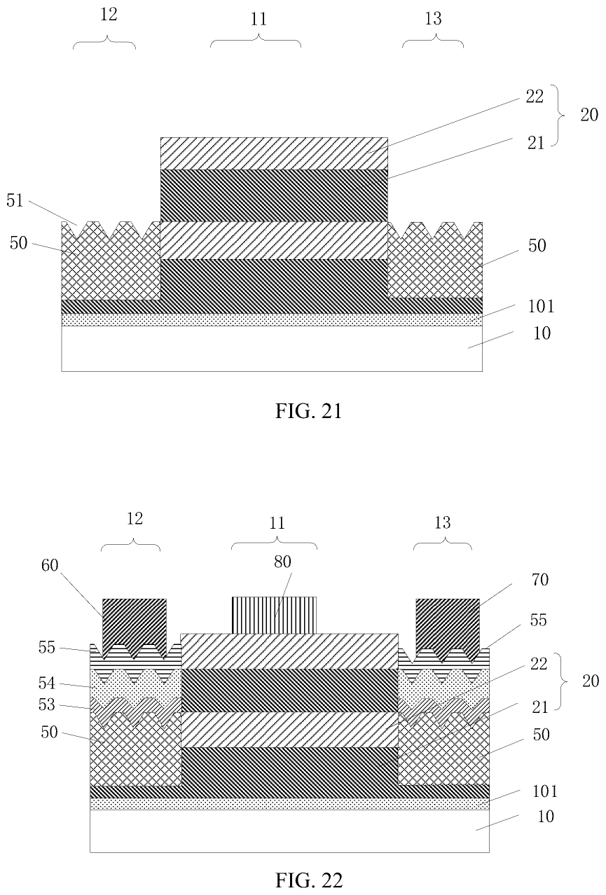

As shown in FIG. 21, in some embodiments, the difference between step 1804 and step 1104 is that the surface of the N-type heavily doped layer 50 away from the substrate 10 is closer to the substrate 10 than the surface of the first channel layer 21 farthest away from the substrate 10, which will not be repeated here.

Step 1805: a back barrier layer 53, a second channel layer 54 and a second barrier layer 55 are sequentially formed at a side of the N-type heavily doped layer 50 away from the substrate 10, and are conformally stacked on the N-type heavily doped layer 50.

As shown in FIG. 22, in some embodiments, the back barrier layer 53, the second channel layer 54 and the second barrier layer 55 may be sequentially formed by using a process such as chemical vapor deposition or epitaxial growth.

The back barrier layer 53 conformally covers the N-type heavily doped layer 50. For example, the back barrier layer 53 is made of AlN or AlGaN, and the thickness of the back barrier layer 53 is less than the thickness of the N-type heavily doped layer 50 and less than the thickness of the second channel layer 54.

The second channel layer 54 conformally covers the back barrier layer 53. For example, the second channel layer 54 is made of unintentionally doped GaN.

The second barrier layer 55 conformally covers the second channel layer 54. For example, the second barrier layer 55 is made of AlGaN.

The back barrier layer 53 can prevent the N-type doped element in the N-type heavily doped layer 50 from diffusing to the second channel layer 54, and on the other hand, new 2DEG is formed between the back barrier layer 53 and the N-type heavily doped layer 50, thereby reducing the overall resistance of the device.

Step 1806: a source electrode 60 and a drain electrode 70 are formed at a side of the N-type heavily doped layers 50 away from the substrate 10, and a gate electrode 80 is formed at a side of the channel structure 20 away from the substrate 10.

As shown in FIG. 22, in some embodiments, the gate electrode 80 is in the gate region and is in contact with the first barrier layer 22 farthest away from the substrate 10. The source electrode 60 and the drain electrode 70 are respectively in contact with a surface of the second barrier layers 55 away from the substrate 10, to be respectively electrically connected to the N-type heavily doped layers 50.

The manufacturing method of the semiconductor structure in this embodiment has the same inventive concept and the similar beneficial effects as the semiconductor structure, and details not described in this embodiment may refer to the above embodiments of the semiconductor structure.

The above description are only preferred embodiments of the present disclosure and is not intended to limit the present disclosure, and any modifications, equivalent substitutions, improvements and the like made within the spirit and the principle of the present disclosure shall fall within the protection scope of the present disclosure.

What is claimed is:

1. A semiconductor structure, comprising:
a substrate;
a channel structure at a side of the substrate, wherein the channel structure comprises a first channel layer above the substrate and a first barrier layer above the first channel layer, wherein the semiconductor structure comprises a gate region, and a source region and a drain region at both sides of the gate region, the channel structure in the source region is provided with a first groove, and the channel structure in the drain region is provided with a second groove; and
two N-type heavily doped layers respectively located in the first groove and the second groove;
wherein a surface of the N-type heavily doped layer away from the substrate has a plurality of V-shaped pits.

2. The semiconductor structure according to claim 1, wherein the N-type heavily doped layers is a single-layer structure or a superlattice structure.

3. The semiconductor structure according to claim 2, wherein when the N-type heavily doped layer is the single-layer structure, the N-type heavily doped layer is made of InGaN.

4. The semiconductor structure according to claim 2, wherein when the N-type heavily doped layer is the superlattice structure, the N-type heavily doped layer comprises at least two periodically stacked material layers which are respectively selected from an InGaN layer, a GaN layer, a GaAs layer, an AlGaAs layer or an InGaAs layer.

5. The semiconductor structure according to claim 4, wherein a surface of each of the at least two material layers away from the substrate has a plurality of V-shaped pits, wherein an opening width of a V-shaped pit of a material layer away from the substrate is greater than an opening width of a V-shaped pit of a material layer close to the substrate.

6. The semiconductor structure according to claim 1, wherein a distance between the surface of the N-type heavily doped layer away from the substrate and the substrate is greater than or equal to a distance between a surface of the first channel layer away from the substrate and the substrate.

7. The semiconductor structure according to claim 6, further comprising:
a cap layer covering a surface of the N-type heavily doped layer away from the substrate.

8. The semiconductor structure according to claim 1, further comprising:
a back barrier layer covering the N-type heavily doped layer, wherein the back barrier layer comprises back barrier layer V-shaped pits;
a second channel layer covering the back barrier layer, wherein the second channel layer comprises second channel layer V-shaped pits; and
a second barrier layer covering the second channel layer, wherein the second barrier layer comprises second barrier layer V-shaped pits.

9. The semiconductor structure according to claim 8, wherein a surface of the second channel layer away from the substrate is flush with a surface of the first channel layer away from the substrate.

10. The semiconductor structure according to claim 8, wherein,
the back barrier layer conformally covers the N-type heavily doped layer, the second channel layer conformally covers the back barrier layer, and the second barrier layer conformally covers the second channel layer; or
an opening width of the back barrier layer V-shaped pit is greater than an opening width of the second channel layer V-shaped pit, and the opening width of the second channel layer V-shaped pit is greater than an opening width of the second barrier layer V-shaped pit.

11. The semiconductor structure according to claim 1, wherein there are a plurality of channel structures stacked above the substrate, wherein a bottom of the first groove and a bottom of the second groove are respectively lower than a surface of the first channel layer away from the substrate in a channel structure closest to the substrate.

12. The semiconductor structure according to claim 11, further comprising:
a cap layer covering the surface of the N-type heavily doped layer away from the substrate, wherein a surface of a first channel layer away from the substrate in a channel structure furthest away from the substrate in the plurality of channel structures is flush with the surface of the N-type heavily doped layer away from the substrate.

13. The semiconductor structure according to claim 11, further comprising:
a back barrier layer covering the surface of the N-type heavily doped layer away from the substrate, wherein the back barrier layer comprises back barrier layer V-shaped pits;
a second channel layer covering the back barrier layer, wherein the second channel layer comprises second channel layer V-shaped pits; and
a second barrier layer covering the second channel layer, wherein the second barrier layer comprises second barrier layer V-shaped pits;
wherein a surface, away from the substrate, of a first channel layer farthest away from the substrate is flush with a surface of the second channel layer away from the substrate; and/or
a surface, away from the substrate, of a first channel layer other than the first channel layer farthest away from the substrate is flush with the surface of the N-type heavily doped layer away from the substrate.

14. The semiconductor structure according to claim 1, further comprising:
a gate electrode in the gate region and at a side of the channel structure away from the substrate; and
a source electrode in the source region and a drain electrode in the drain region, wherein the source electrode and the drain electrode are respectively at a side of the two N-type heavily doped layers away from the substrate.

15. A method for manufacturing a semiconductor structure, comprising:
providing a substrate;
forming a channel structure above the substrate, wherein the semiconductor structure comprises a gate region, and a source region and a drain region at both sides of the gate region, and the channel structure comprises a first channel layer above the substrate and a first barrier layer above the first channel layer;
forming a first groove in the source region and a second groove in the drain region; and
forming N-type heavily doped layers in the first groove and the second groove respectively, wherein a plurality of V-shaped pits are formed at a surface of the N-type heavily doped layer away from the substrate.

16. The method according to claim 15, wherein forming the N-type heavily doped layer comprises:
forming a superlattice structure comprising at least two material layers which are periodically stacked through times of secondary epitaxial growth, wherein an opening width of a V-shaped pit of a material layer away from the substrate is greater than an opening width of a V-shaped pit of a material layer close to the substrate.

17. The method according to claim 15, wherein after forming the N-type heavily doped layers, the method further comprises:
forming a cap layer at a side of the N-type heavily doped layer away from the substrate.

18. The method according to claim 15, wherein after forming the N-type heavily doped layers, the method further comprises:
forming a back barrier layer on the N-type heavily doped layer away from the substrate and comprising back barrier layer V-shaped pits, a second channel layer on the back barrier layer away from the substrate and comprising second channel layer V-shaped pits, and a second barrier layer on the second channel layer and comprising second barrier layer V-shaped pits.

19. The method according to claim 15, further comprising:
forming a source electrode in the source region and a drain electrode in the drain region at a side of the N-type heavily doped layer away from the substrate; and
forming a gate electrode at a side of the channel structure away from the substrate.

20. The semiconductor structure according to claim 1, the V-shaped pits, due to the differences in crystal plane growth orientations and growth rates at the different positions resulting from the dislocation defects in the N-type heavily doped layer, are spontaneously formed.
